(19) United States
(12) Patent Application Publication
(10) Pub. No.: US 2020/0116759 A1
(43) Pub. Date: Apr. 16, 2020

(54) TEST PROBE ASSEMBLY FOR HIGH FREQUENCY DEVICE CHARACTERIZATION

(71) Applicant: XCERRA CORPORATION, Norwood, MA (US)

(72) Inventors: Jason Mroczkowski, St. Paul, MN (US); Nadia Steckler, St. Paul, MN (US); James Hattis, St. Paul, MN (US); Ken Snyder, St. Paul, MN (US); Scott Hanson, St. Paul, MN (US)

(21) Appl. No.: 16/593,200

(22) Filed: Oct. 4, 2019

Related U.S. Application Data
(60) Provisional application No. 62/744,463, filed on Oct. 11, 2018.

(51) Int. Cl. G01R 1/067; H01P 5/10; H01P 3/00; H01R 24/40

(52) U.S. Cl. CPC G01R 1/06766; H01P 5/10; H01P 3/006; H01R 2103/00; G01R 1/06772; H01R 2201/20; H01R 24/40

(57) ABSTRACT

A test probe assembly includes a mounting fixture, a co-planar waveguide lead frame having a device contact point, where the co-planar waveguide lead frame is mounted to the mounting fixture, and at least one radio frequency (RF) connector assembly electrically coupled with the co-planar waveguide lead frame.

### RELATED APPLICATION

This application claims priority to U.S. Provisional Application No. 62/744,463 that was filed on Oct. 11, 2018. The entire content of the application referenced above is hereby incorporated by reference herein.

### TECHNICAL FIELD

Compliant test probe capable of probing non coplanar contacts and related methods.

### TECHNICAL BACKGROUND

Radio Frequency (RF) characterization probes provide a precision impedance matched contact geometry to probe small transmission line structures on semiconductor devices, printed circuit boards (PCB), semiconductor wafers, or any other small geometries that need RF characterization.

RF characterization probes are available. However, the probes available on the current market are expensive, fragile, and not all are field-repairable. The current probes are made using small coaxial cable and either machining the contact end of the probe or soldering small flanges on to the contact end to provide a coplanar termination. These are not field repairable nor are they configurable. What is needed is a lower cost, more robust, field-reparable, and more configurable probe.

### SUMMARY

A test probe assembly includes a mounting fixture, a co-planar waveguide lead frame having a device contact point, where the co-planar waveguide lead frame is mounted to the mounting fixture, and at least one radio frequency (RF) connector electrically coupled with the co-planar waveguide lead frame.

In one or more embodiments, the co-planar waveguide lead frame has a metal layer and a substrate layer.

In one or more embodiments, the metal layer has a signal lead surround on two sides by a ground.

In one or more embodiments, a gap and signal width are defined to match impedance of test equipment.

In one or more embodiments, the gap and the signal width are defined to match impedance of a device under test (DUT).

In one or more embodiments, the co-planar waveguide lead frame is a single ground-signal-ground co-planar waveguide lead frame.

In one or more embodiments, the co-planar waveguide lead frame is a single ground-signal-signal-ground co-planar waveguide lead frame.

In one or more embodiments, the co-planar waveguide lead frame is of any number of combinations of signal and ground probe cluster configurations for any custom individual device under test a single ground-signal-signal-ground co-planar waveguide lead frame.

In one or more embodiments, the co-planar waveguide lead frame can include a single-ended to differential balun.

In one or more embodiments, the co-planar waveguide lead frame is multiple ground-signal-ground configuration(s) of co-planar waveguide lead frame.

In one or more embodiments, the co-planar waveguide lead frame has mounting structure.

In one or more embodiments, the mounting structure includes one or more of screw holes or dowel pin slots.

In one or more embodiments, the mounting structure includes one or more compression screws to hold the connector in place.

In one or more embodiments, the at least one RF connector assembly is defined by a longitudinal axis, the longitudinal axis disposed at about a 45 degree angle relative to a plane defining in part the co-planar waveguide lead frame.

In one or more embodiments, the RF connector assembly has a center conductor assembly compression mounted to the co-planar waveguide lead frame.

In one or more embodiments, the RF connector assembly has a center conductor assembly, the center conductor assembly includes one or more spacers.

In one or more embodiments, the one or more spacers are cross-linked polystyrene microwave plastic spacers.

In one or more embodiments, a test probe assembly includes a mounting fixture, and a co-planar waveguide lead frame with a device contact point. The co-planar waveguide lead frame is mounted to the mounting fixture. At least one radio frequency (RF) connector is electrically coupled with the co-planar waveguide lead frame. The at least one RF connector assembly includes a center conductor assembly which includes a center conductor, and the center conductor extends from a first end to a second end and is defined in part by a conductor longitudinal axis.

In one or more embodiments, the center conductor includes a tapered end at the first end.

In one or more embodiments, the center conductor includes one or more recessed portions.

In one or more embodiments, the test probe assembly further includes one or more spacers disposed within the one or more recessed portions.

In one or more embodiments, the one or more spacers are cross-linked polystyrene microwave plastic spacers.

In one or more embodiments, the one or more spacers have a disc shape.

In one or more embodiments, the at least one RF connector assembly is defined by a longitudinal axis, the longitudinal axis disposed at about a 45 degree angle relative to a plane defining in part the co-planar waveguide lead frame.

In one or more embodiments, a gap and signal width are defined to match impedance of test equipment.

In one or more embodiments, the gap and the signal width are defined to match impedance of a DUT.

These and other embodiments, aspects, advantages, and features of the present invention will be set forth in part in the description which follows, and will become apparent to those skilled in the art by reference to the following description of the invention and referenced drawings or by practice of the invention. The aspects, advantages, and features of the invention are realized and attained by means of the instrumentalities, procedures, and combinations particularly pointed out in the appended claims and their equivalents.

### BRIEF DESCRIPTION OF THE FIGURES

FIG. 1 illustrates a perspective view of a test probe assembly as constructed in one or more embodiments.

FIG. 2 illustrates a perspective view of a test probe assembly as constructed in one or more embodiments.

FIG. 3 illustrates a top view of a test probe assembly as constructed in one or more embodiments.

FIG. 4 illustrates a side view of a test probe assembly as constructed in one or more embodiments.

FIG. 5 illustrates a front view of a test probe assembly as constructed in one or more embodiments.

FIG. 6 illustrates a bottom view of a test probe assembly as constructed in one or more embodiments.

FIG. 7 illustrates a side cross-sectional view of a test probe assembly as constructed in one or more embodiments.

FIG. 8 illustrates an exploded perspective view of a test probe assembly as constructed in one or more embodiments.

FIG. 9 illustrates a top view of a lead frame assembly as constructed in one or more embodiments.

FIG. 10 illustrates an enlarged view of a portion of a lead frame assembly as constructed in one or more embodiments.

FIG. 11 illustrates an enlarged view of a portion of a lead frame assembly as constructed in one or more embodiments.

FIG. 12 illustrates a side view of a portion of a lead frame assembly as constructed in one or more embodiments.

FIG. 13 illustrates an enlarged, bottom perspective view of a portion of a test probe assembly as constructed in one or more embodiments.

FIG. 14 illustrates a perspective view of a test probe assembly as constructed in one or more embodiments.

FIG. 15 illustrates an enlarged perspective view of a portion of a test probe assembly as constructed in one or more embodiments.

FIG. 16 illustrates an exploded perspective view of a center conductor assembly as constructed in one or more embodiments.

FIG. 17 illustrates a perspective view of a center conductor assembly as constructed in one or more embodiments.

FIG. 18 illustrates a perspective view of a portion of a center conductor assembly as constructed in one or more embodiments.

FIG. 19 illustrates an enlarged view of a portion of a lead frame assembly having a GSG configuration as constructed in one or more embodiments.

FIG. 20 illustrates an enlarged view of a portion of a lead frame assembly having a GS configuration as constructed in one or more embodiments.

FIG. 21 illustrates an enlarged view of a portion of a lead frame assembly having a GSSG configuration as constructed in one or more embodiments.

FIG. 22 illustrates an enlarged view of a portion of a lead frame assembly having a GSGSG configuration as constructed in one or more embodiments.

FIG. 23 illustrates a perspective view of a GSGSG test probe assembly as constructed in one or more embodiments.

FIG. 24 illustrates a view of a lead frame assembly as constructed in one or more embodiments.

FIG. 25 illustrates a perspective view of a GSGSGSG test probe assembly as constructed in one or more embodiments.

### DETAILED DESCRIPTION

The following detailed description includes references to the accompanying drawings, which form a part of the detailed description. The drawings show, by way of illustration, specific embodiments in which the apparatus may be practiced. These embodiments, which are also referred to herein as “examples” or “options,” are described in enough detail to enable those skilled in the art to practice the present embodiments. The embodiments may be combined, other embodiments may be utilized or structural or logical changes may be made without departing from the scope of the invention. The following detailed description is, therefore, not to be taken in a limiting sense and the scope of the invention is defined by the appended claims and their legal equivalents.

In this document, the terms “a” or “an” are used to include one or more than one, and the term “or” is used to refer to a nonexclusive “or” unless otherwise indicated. In addition, it is to be understood that the phraseology or terminology employed herein, and not otherwise defined, is for the purpose of description only and not of limitation.

An integrated circuit test probe assembly 100 is described herein, and shown in the drawings. The test probe assembly 100 includes a co-planar waveguide construction, combined with a mechanically mounted custom radio frequency (RF) connector to provide matched compliant probing mechanism for probing semiconductor devices, PCBs, substrates, bare die, etc. at frequencies up to 110 GHz or even up to 1 THz. The construction and assembly allows for simple customization and replacement of individual components. The probe assembly is more robust than previous probes, and can be repaired and configured in the field.

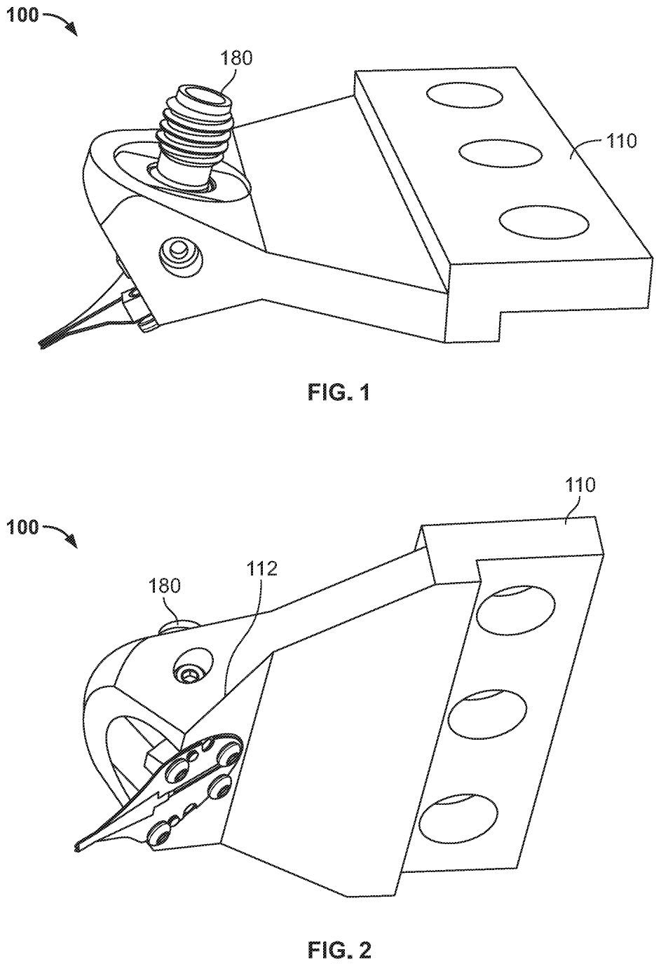

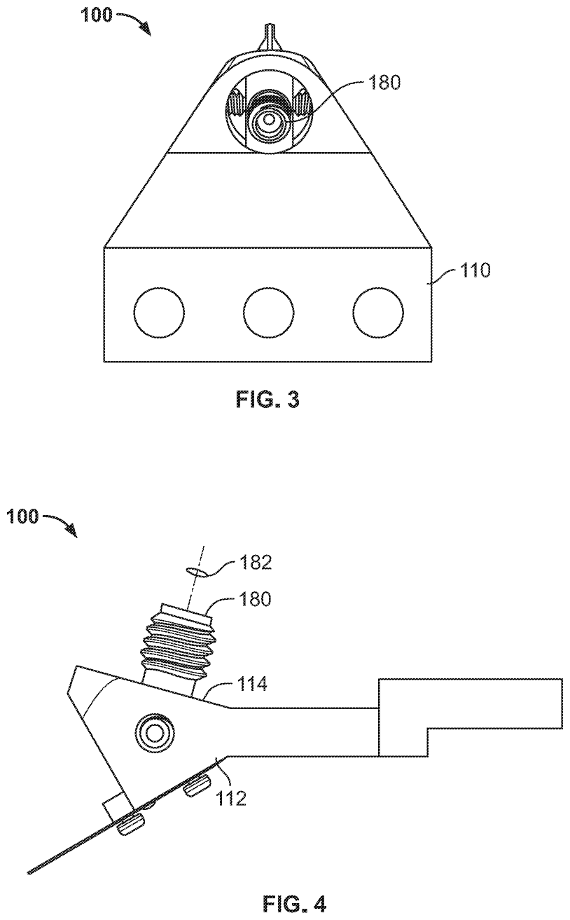

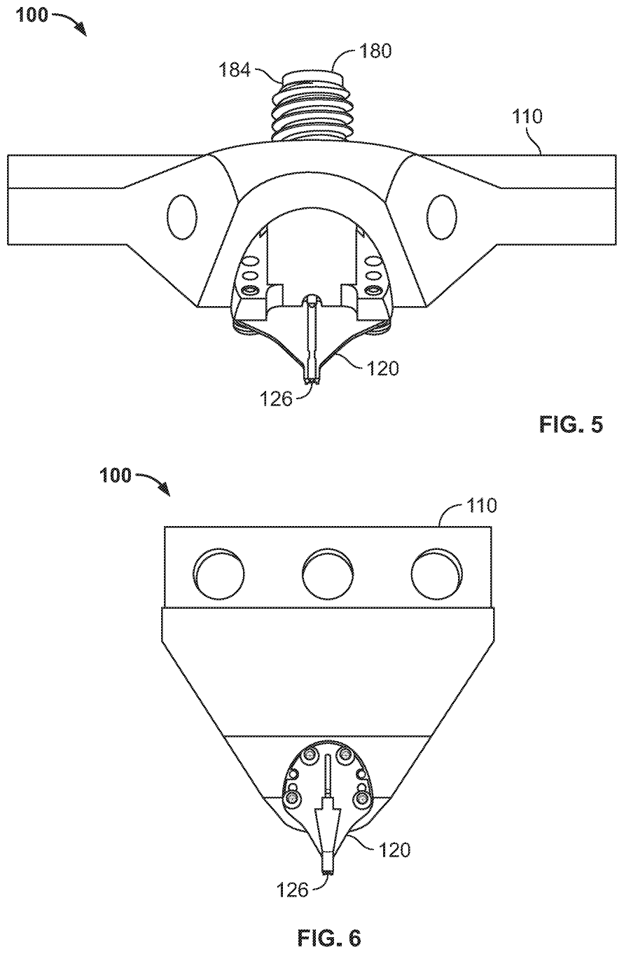

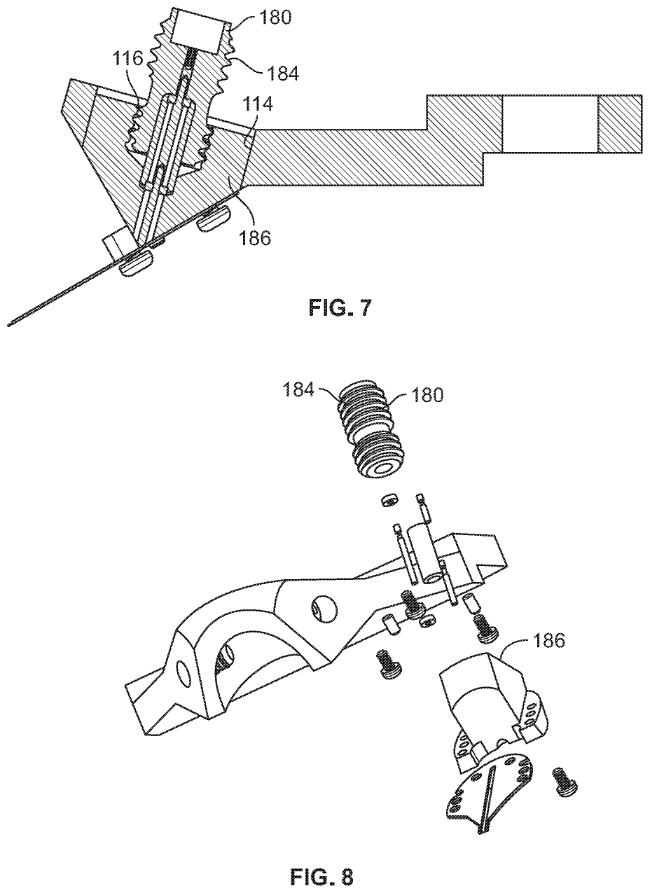

The test probe assembly 100 is shown in general in FIGS. 1-6 includes a mounting fixture 110, a co-planar waveguide (CPW) lead frame 120, and an RF connector assembly 180. The co-planar waveguide lead frame 120 is mounted to the mounting fixture 110. The RF connector assembly is electrically coupled with the co-planar waveguide lead frame 120.

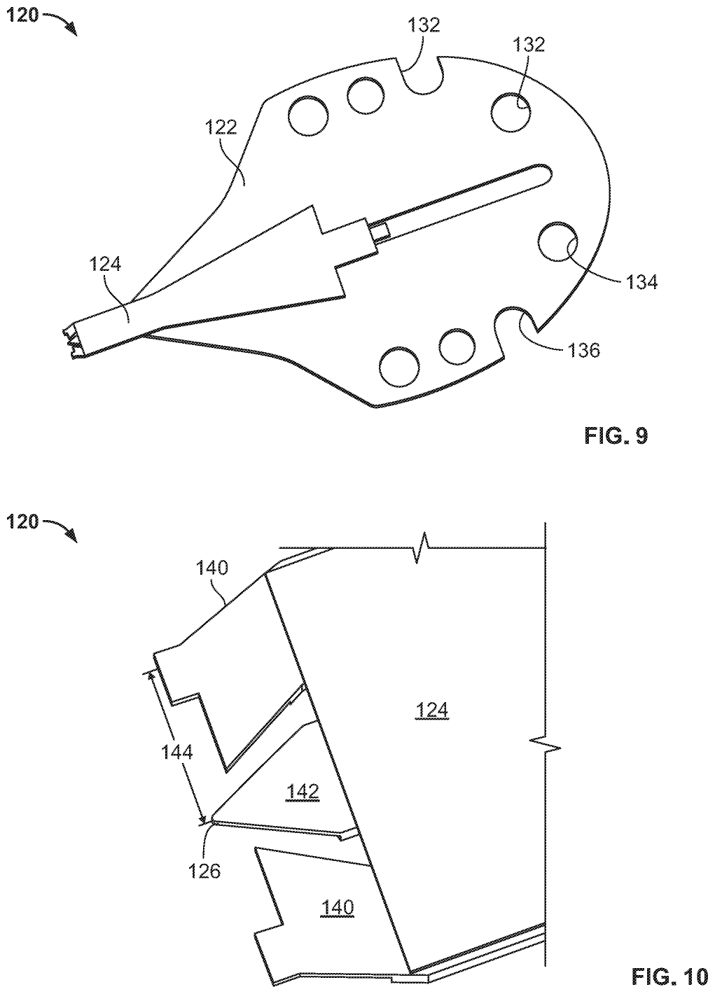

Referring to FIGS. 9-13, the co-planar waveguide lead frame 120 is shown in greater detail. The co-planar waveguide lead frame 120 includes a metal layer 122 and a substrate layer 124. The metal layer 122 includes a signal lead surrounded on two sides by a ground, creating a co-planar waveguide transmission line, and extends to a device contact point 126. The gap 128 and signal width are defined to match the impedance of the test equipment and the device under test (DUT). In one or more embodiments, the impedance is 50 ohms. The matched impedances could be customized depending on the application.

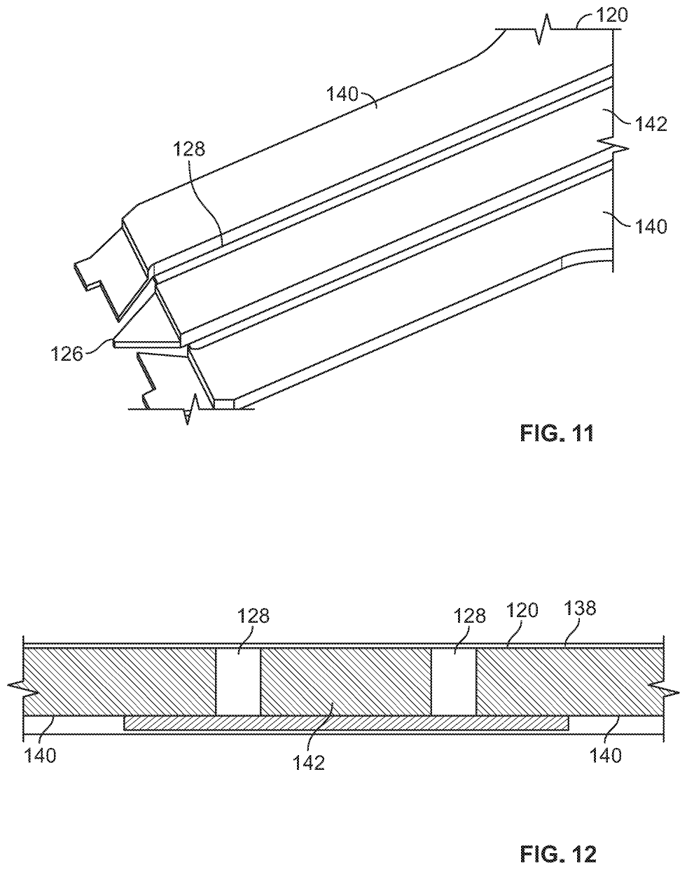

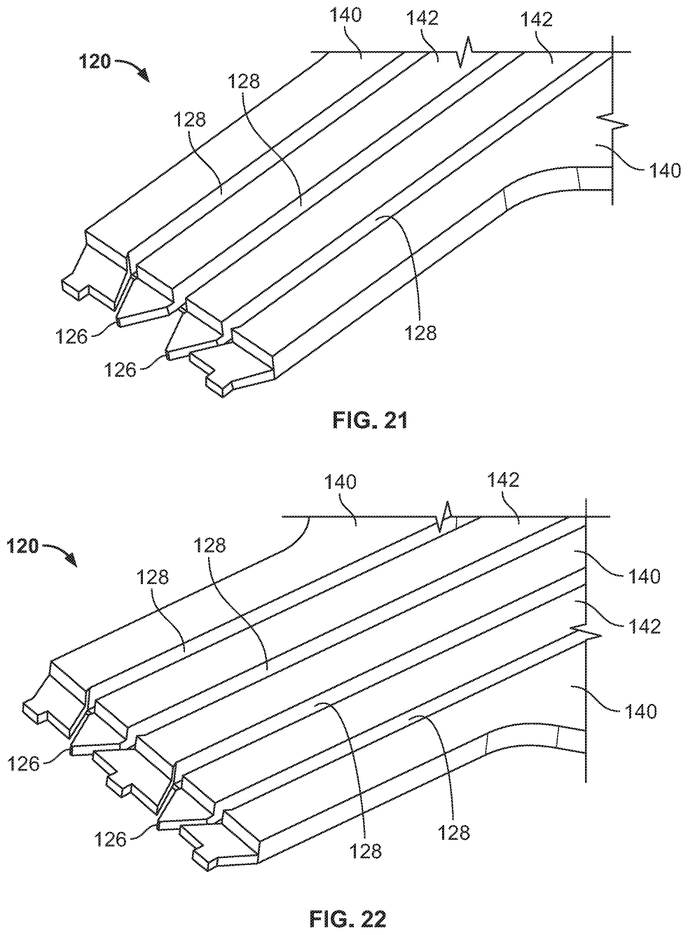

In one or more embodiments, the co-planar waveguide lead frame 120 includes a single ground-signal-ground co-planar waveguide, as shown in FIGS. 11-12. In one or more embodiments, the co-planar waveguide lead frame 120 can support a single ended ground-signal (GS) transmission lines, for instance matched to 50 ohms, as shown in FIGS. 20, 24. In one or more embodiments, the co-planar waveguide lead frame 120 includes a ground-signal-signal-ground (GSSG) transmission lines, which are typically matched to 100 ohm impedance, as shown in FIG. 21. For a GSSG configuration, two RF connector assemblies would be mounted on a single assembly.

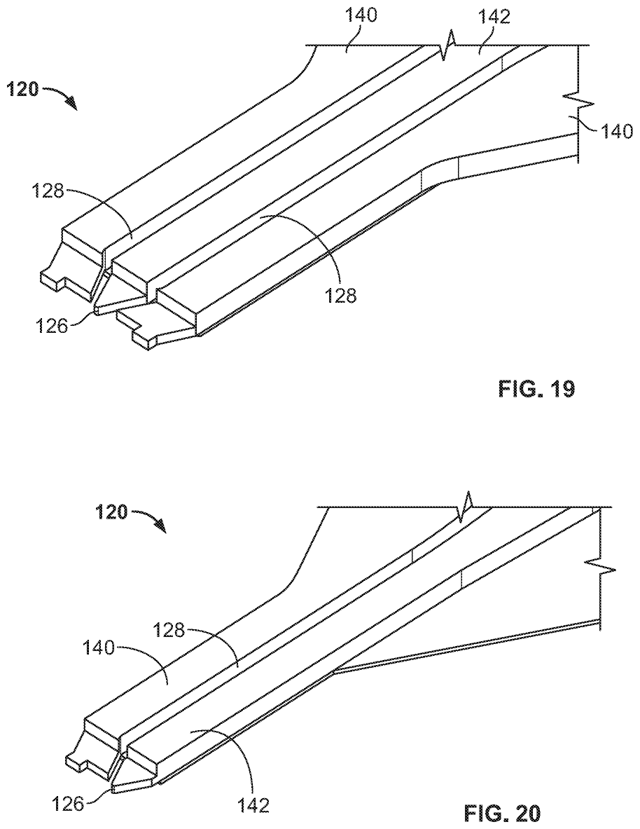

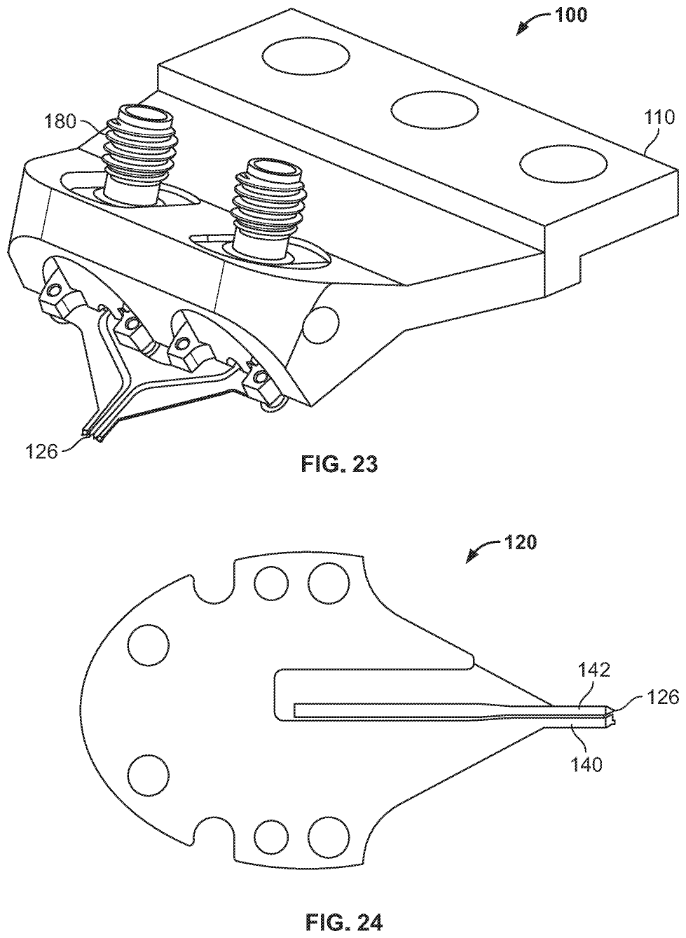

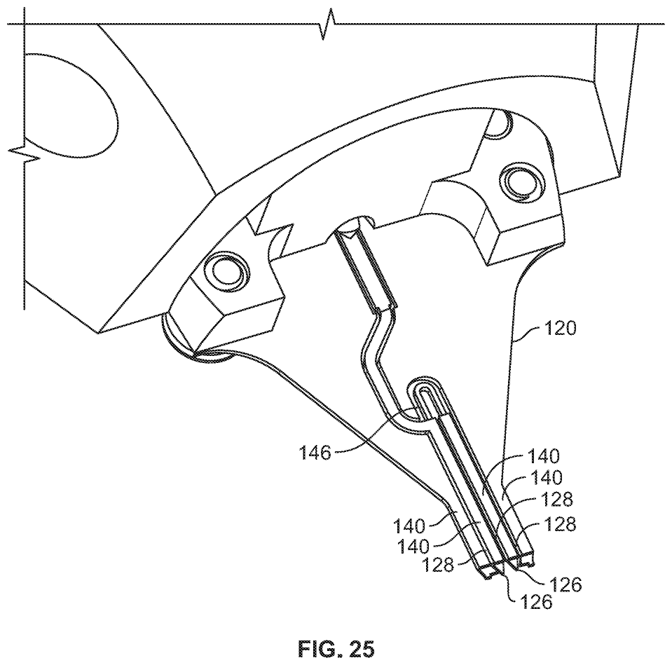

In one or more embodiments, the co-planar waveguide lead frame is a single ground-signal-ground co-planar (GSG) waveguide lead frame, as shown in FIG. 19. In one or more embodiments, the co-planar waveguide lead frame is a single ground-signal-signal-ground (GSSG) co-planar waveguide lead frame, as shown in FIG. 21. In one or more embodiments, the co-planar waveguide lead frame is a single ground-signal-ground-signal-ground (GSGSG) co-planar waveguide lead frame, as shown in FIGS. 22 and 23. For a GSGSG configuration, two RF connector assemblies 180 would be mounted on a single assembly 100, as shown in FIG. 23. In one or more embodiments, the co-planar waveguide lead frame is a single ground-signal-ground-signal-ground-signal-ground (GSGSGSG) co-planar waveguide lead frame, as shown in FIG. 25. In one or more embodiments, the co-planar waveguide lead frame includes a single-ended to differential balun 146, which is used to shift phase, as shown in FIG. 25. In one or more embodiments, the co-planar waveguide lead frame is multiple ground-signal-ground co-planar waveguide lead frame. The co-planar waveguide lead frame 120 can be customized for any ground/signal pitch 144.

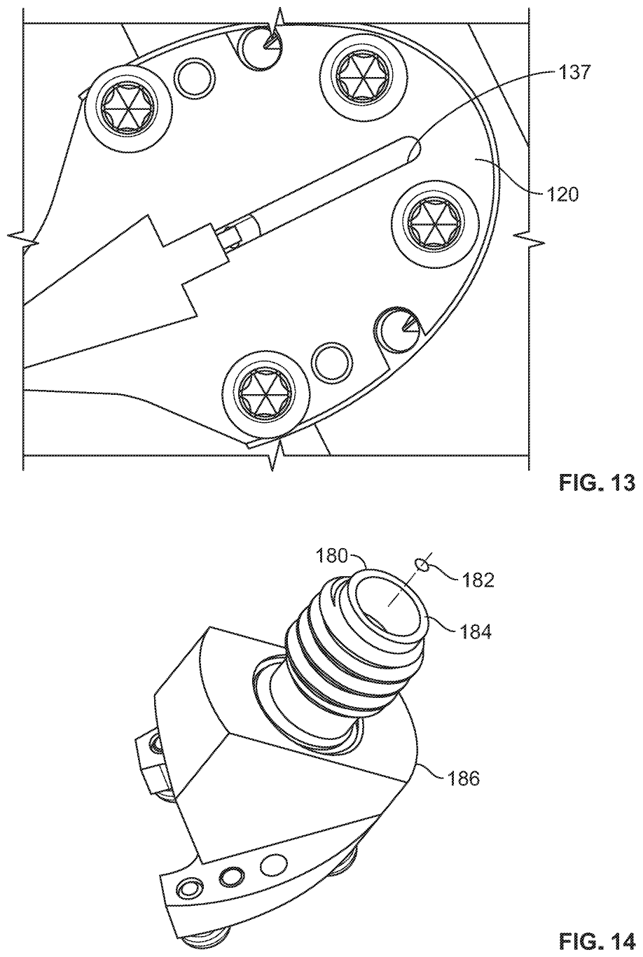

The co-planar waveguide lead frame 120 is defined in part by a plane 138, as shown in FIG. 12, and further includes mounting structure 132, as shown in FIG. 9. In one or more embodiments, the mounting structure 132 includes screw holes 134. In one or more embodiments, the mounting structure 132 includes dowel pin slots 136. The mounting structure 132 is used to receive structure therein to secure the co-planar waveguide lead frame 120 to the mounting fixture 110. The mounting structure 132 allows for the co-planar waveguide lead frame 120 to be interchanged for different DUT requirements, and allows for the co-planar waveguide lead frame 120 to be replaceable. The co-planar waveguide lead frame 120 further includes a conductor slot 137, as shown in FIG. 13.

The RF connector assembly allows connection from the co-planar waveguide lead frame 120 to the test equipment through, for example, 1 mm, 1.85 mm, 2.92 mm, and SMA standard connector interfaces. The RF connector assembly includes a threaded portion that can be replaceable for any cable standard available. The RF connector assembly 180 provides the shortest path from the cable to the co-planar waveguide lead frame 120 and is fully impedance controlled from the cable connection to the interface of the co-planar waveguide lead frame 120.

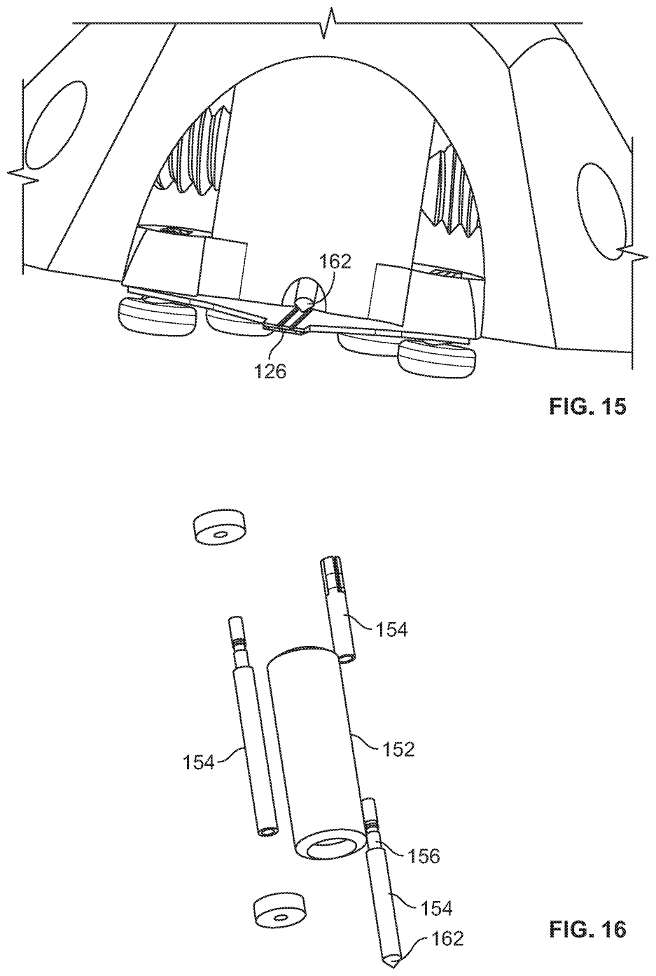

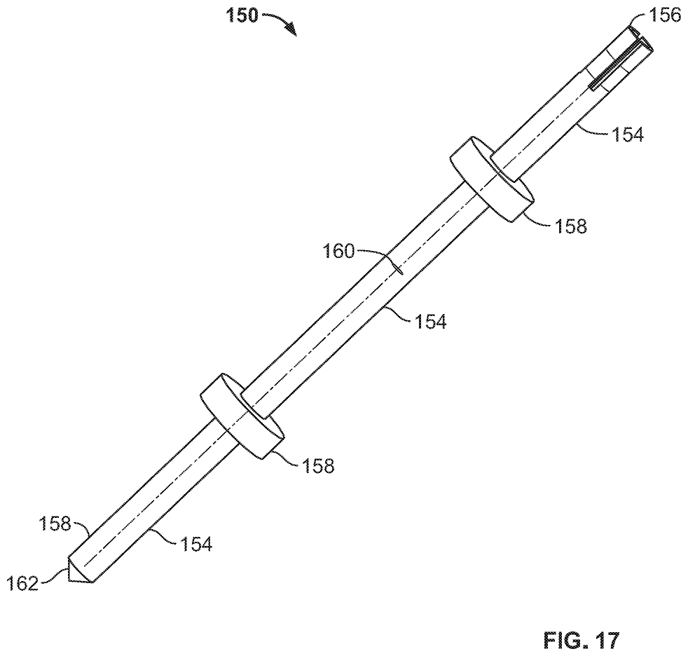

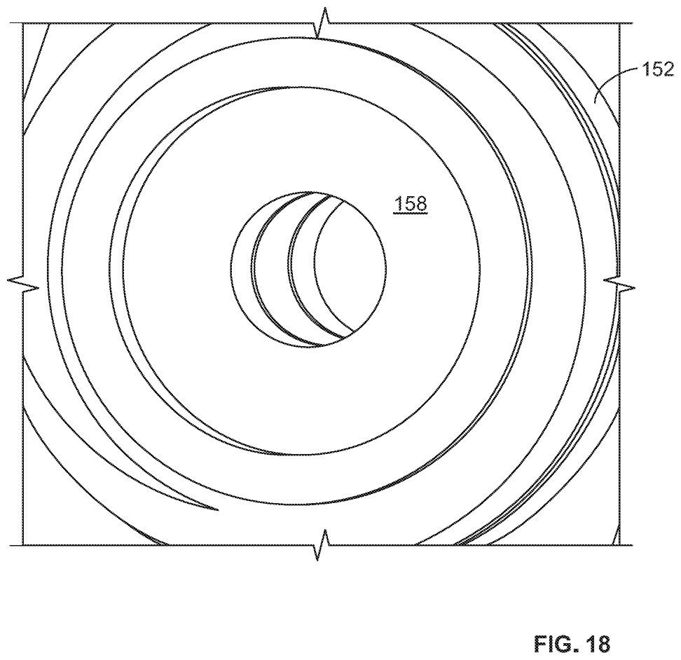

The RF connector assembly 180 is defined in part by a longitudinal axis 182 as shown in FIGS. 4 and 14. The RF connector assembly includes a connector 184, and a connector body 186. The connector body 186 includes a threaded opening 116 that receives the threaded connector 184 therein. In one or more embodiments, the RF connector assembly 180 is angled relative to the co-planar waveguide lead frame 120 such that the connector longitudinal axis 182 is disposed at a 45 degree angle relative to the plane 138 of the co-planar waveguide lead frame 120. The 45 degree angle provides a matched impedance launch from the RF connector assembly 180 to the co-planar waveguide lead frame 120.

The barrel of the RF connector assembly 180 can be formed, for example, from common rod stock. The physical connection from the connector to the co-planar waveguide lead frame 120 is accomplished using cap screws located on the bottom of the RF connector assembly. The screw holes in the body can be tapped to allow mounting of the co-planar waveguide lead frame 120 directly to the RF connector assembly or they can be through holes to allow the connector to sandwich the co-planar waveguide lead frame 120 between the RF connector assembly 180 and another body of material under the co-planar waveguide lead frame 120.

In one or more embodiment, the RF connector assembly 180 includes a center conductor assembly 150. The at least one RF connector assembly 180 includes a center conductor assembly 150 which includes a center conductor 154 and a housing 152. The center conductor 154 extends from a first end 156 to a second end 158 and is defined in part by a conductor longitudinal axis 160. In one or more embodiments, the center conductor 154 includes a tapered end 162 at the second end 158. In one or more embodiments, the center conductor 154 includes one or more recessed portions 156. In one or more embodiments, the test probe assembly further includes one or more spacers 158 disposed within the one or more recessed portions 156. In one or more embodiments, the one or more spacers 158 are cross-linked polystyrene microwave plastic spacers. In one or more embodiments, the one or more spacers 158 have a disc shape. The spacers 158 are disposed between the housing 152 and the center conductor 154 (See FIG. 18). The housing 152 holds the co-planar waveguide lead frame 120 and RF connector assembly 180 in a test position for attachment to a probing station or similar manipulator equipment. The housing 152 can be customized in length and width. The angled side allows multiple housing assemblies set adjacent to each other to provide closely spaced contacts on the DUT to be probed.

The center conductor 154 of the center conductor assembly 150 maximizes the impedance match at the interface between the center conductor 154 and the co-planar waveguide lead frame 120. The center conductor 154 is tapered and compression mounted, in one embodiment, to the co-planar waveguide lead frame 120 such that it ensures a reliable connection and provides optimal impedance match between connector and lead frame. The taper is angled to maximize the surface area of contact to the co-planar waveguide lead frame 120, as shown in FIG. 15. In one or more embodiments, the center conductor assembly 150 includes small spacers that are captivated on the center conductor 154. In one or more embodiments, the center conductor 154 is formed of two or more, or three separate pieces that are press fit together forming recessed portions 156. The spaces minimize the insertion loss of the conductor while maintaining temperature capability to a desired temperature, for example 150 deg. C.

The test probe assembly includes a co-planar waveguide construction, combined with a mechanically mounted custom radio frequency (RF) connector to provide matched compliant probing mechanism for probing semiconductor devices, PCBs, substrates, bare die, etc. at frequencies up to 110 GHz or even up to 1 THz. The probe tip is independently compliant and can bend to be used on non-planar surfaces. The construction and assembly allows for simple customization and replacement of individual components. The probe assembly is more robust than previous probes, and can be repaired and configured in the field. The lead frame can be customized for any ground/signal pitch required for testing (typical pitches range from 50 to 1250 um). The lead frame is replaceable and can be interchanged for different DUT requirements.

It is to be understood that the above description is intended to be illustrative, and not restrictive. Many other embodiments will be apparent to those of skill in the art upon reading and understanding the above description. It should be noted that embodiments discussed in different portions of the description or referred to in different drawings can be combined to form additional embodiments of the present application. The scope should, therefore, be determined with reference to the appended claims, along with the full scope of equivalents to which such claims are entitled.

What is claimed is:

1. A test probe assembly comprising:
a mounting fixture;
at least one co-planar waveguide lead frame having a device contact point, the co-planar waveguide lead frame mounted to the mounting fixture; and
at least one radio frequency (RF) connector assembly electrically coupled with the co-planar waveguide lead frame.

2. The test probe assembly as recited in claim 1, wherein the at least one co-planar waveguide lead frame has a metal layer and a substrate layer.

3. The test probe assembly as recited in claim 2, wherein the metal layer has a signal lead surrounded on two sides by a ground.

4. The test probe assembly as recited in claim 1, wherein a gap and signal width are defined to match impedance of test equipment.

5. The test probe assembly as recited in claim 4, wherein the gap and the signal width are defined to match impedance of a device under test (DUT).

6. The test probe assembly as recited in claim 1, wherein the at least one co-planar waveguide lead frame is a single ground-signal-ground co-planar waveguide lead frame.

7. The test probe assembly as recited in claim 1, wherein the at least one co-planar waveguide lead frame is at least one of a single ground-signal-signal-ground co-planar waveguide lead frame, a single ground-signal-ground-signal-ground co-planar waveguide lead frame, or a single ground-signal-ground-signal-ground-signal-ground co-planar waveguide lead frame.

8. The test probe assembly as recited in claim 1, wherein the co-planar waveguide lead frame is a single ended to differential balun.

9. The test probe assembly as recited in claim 1, wherein the at least one co-planar waveguide lead frame includes multiple co-planar waveguide lead frames.

10. The test probe assembly as recited in claim 1, wherein the co-planar waveguide lead frame has mounting structure.

11. The test probe assembly as recited in claim 10, wherein the mounting structure includes one or more of screw holes or dowel pin slots.

12. The test probe assembly as recited in claim 1, wherein the at least one RF connector assembly is defined by a longitudinal axis, the longitudinal axis disposed at about a 45 degree angle relative to a plane defining in part the co-planar waveguide lead frame.

13. The test probe assembly as recited in claim 1, wherein the RF connector assembly has a center conductor assembly compression mounted to the co-planar waveguide lead frame.

14. The test probe assembly as recited in claim 1, wherein the RF connector assembly has a center conductor assembly having at least one center conductor, the center conductor includes one or more spacers.

15. A test probe assembly comprising:
a mounting fixture;
a co-planar waveguide lead frame having a device contact point, the co-planar waveguide lead frame mounted to the mounting fixture; and
at least one radio frequency (RF) connector assembly electrically coupled with the co-planar waveguide lead frame, the at least one RF connector assembly includes a connector body and a center conductor assembly, the center conductor assembly including a center conductor extending from a first end to a second end and is defined in part by a conductor longitudinal axis.

16. The test probe assembly as recited in claim 15, wherein the center conductor includes a tapered end at the first end.

17. The test probe assembly as recited in claim 15, wherein the center conductor includes one or more recessed portions.

18. The test probe assembly as recited in claim 17, further comprising one or more spacers disposed within the one or more recessed portions.

19. The test probe assembly as recited in claim 18, wherein the one or more spacers have a disc shape.

20. The test probe assembly as recited in claim 15, wherein the at least one RF connector assembly is defined by a longitudinal axis, the longitudinal axis disposed at about a 45 degree angle relative to a plane defining in part the co-planar waveguide lead frame.

21. The test probe assembly as recited in claim 15, wherein a gap and signal width are defined to match impedance of test equipment.

22. The test probe assembly as recited in claim 21, wherein the gap and the signal width are defined to match impedance of a DUT.
